(19) United States
(12) Patent Application Publication
(10) Pub. No.: US 2025/0391711 A1
(43) Pub. Date: Dec. 25, 2025

(54) HETEROGENOUS INTEGRATION OF SEMICONDUCTOR STRUCTURES

(71) Applicant: Micron Technology, Inc., Boise, ID (US)

(72) Inventors: Bharat Bhushan, Taichung (TW); Terrence B. McDaniel, Boise, ID (US); Kyle K. Kirby, Eagle, ID (US); Akshay N. Singh, Boise, ID (US); Kunal R. Parekh, Boise, ID (US)

(21) Appl. No.: 19/224,361

(22) Filed: May 30, 2025

Related U.S. Application Data
(60) Provisional application No. 63/663,050, filed on Jun. 21, 2024.

(51) Int. Cl. H01L 21/66; H01L 21/768; H01L 23/00; H01L 23/522; H01L 23/532; H01L 25/00; H01L 25/065; H01L 25/18; H10B 80/00

(52) U.S. Cl. CPC H01L 22/32; H01L 21/7682; H01L 21/76877; H01L 22/12; H01L 23/5226; H01L 23/5329; H01L 24/08; H01L 24/80; H01L 25/0657; H01L 25/18; H01L 25/50; H10B 80/00; H01L 2224/08145; H01L 2224/80895; H01L 2224/80896; H01L 2924/14511

(57) ABSTRACT

Systems, devices, and methods for making semiconductor device assemblies, and more particularly for the heterogenous integration of semiconductor structures, are provided herein. A semiconductor device assembly can include a first semiconductor device bonded to a second semiconductor device. The first semiconductor device can include a first dielectric material having first airgaps and a second dielectric material disposed above the first dielectric material and having second airgaps. The first semiconductor device can also include a first metallization layer embedded in the first dielectric material, a second metallization layer disposed between the first dielectric material and the second dielectric material, a third metallization layer at least partially embedded in the second dielectric material, and one or more first vias extending through the first dielectric material between the first metallization layer and the second metallization layer. Each of the one or more first vias can have an aspect ratio of at least 10.

### CROSS-REFERENCE TO RELATED APPLICATION(S)

The present application claims priority to U.S. Provisional Patent Application No. 63/663,050, filed Jun. 21, 2024, the disclosure of which is incorporated herein by reference in its entirety.

### TECHNICAL FIELD

The present disclosure generally relates to semiconductor device assemblies, and more particularly relates to heterogenous integration of semiconductor structures.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of an example semiconductor device assembly.

FIG. 2 is a simplified schematic cross-sectional view of an example semiconductor device assembly in accordance with embodiments of the present technology.

FIG. 3-12 are simplified schematic cross-sectional views illustrating a series of fabrication steps of semiconductor device assemblies in accordance with an embodiment of the present technology.

FIG. 13 is a schematic view showing a system that includes a semiconductor device assembly configured in accordance with an embodiment of the present technology.

FIG. 14 is a flow chart illustrating a method of making a semiconductor device assembly in accordance with an embodiment of the present technology.

A person skilled in the relevant art will understand that the features shown in the drawings are for purposes of illustrations, and variations, including different and/or additional features and arrangements thereof, are possible.

### DETAILED DESCRIPTION

Some packaged semiconductor devices include Back-End-of-Line (BEOL) interconnects designed to efficiently route signals across the chip while minimizing power consumption and signal delay. Manufacturing a BEOL stack can require precise patterning and deposition processes, and ensuring that the semiconductor device can be probed or otherwise tested. BEOL interconnects can be important for mitigating resistance, capacitance, and/or electromigration effects in semiconductor devices, as well as seamlessly integrating with other semiconductor devices for various high-performance computing, communication, and consumer electronics applications.

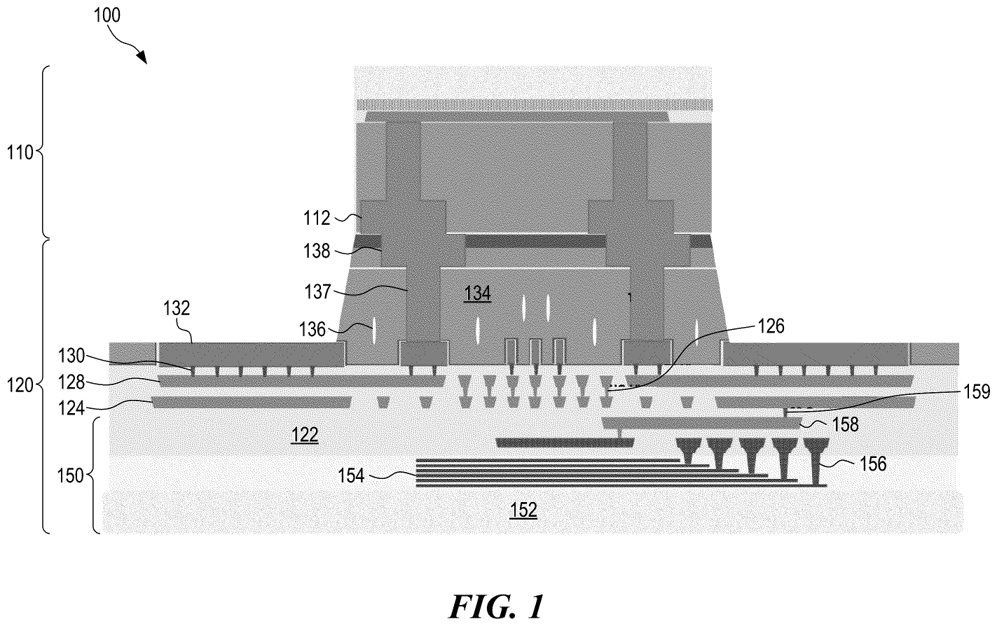

As can be seen with reference to FIG. 1, a semiconductor device assembly 100 includes a first semiconductor structure or device 110 stacked on top of a second semiconductor structure or device 120. Each of the first semiconductor device 110 and the second semiconductor device 120 can include a chip, a wafer, or other structure. The first semiconductor device 110 and the second semiconductor device 120 can be bonded together in a face-to-face arrangement via hybrid bonding, oxide bonding, copper bonding, and/or other suitable bonding techniques such that a substrate 214 of the first semiconductor device 210 is positioned at the top. For example, the first semiconductor device 110 includes one or more first bond pads 112 and the second semiconductor device 120 includes one or more second bond pads 138 coupled to the one or more first bond pads 112.

The second semiconductor device 120 includes a memory structure 150 (e.g., a 3D memory structure, a NAND structure) and various metallization layers deposited on the memory structure 150, as described further herein. The memory structure 150 can include a substrate 152, a plurality of word lines 154, a plurality of bit lines 156, and a first metallization layer 158. The plurality of word lines 154, the plurality of bit lines 156, and the first metallization layer 158 can be deposited in and/or surrounded by a first dielectric material 122 disposed on the substrate 152. In some embodiments, the substrate 152 is composed of silicon, the plurality of word lines 154 and the plurality of bit lines 156 are composed of tungsten, and the first metallization layer 158 is composed of copper. In other embodiments, the aforementioned components of the memory structure 150 can be composed of other suitable materials.

The second semiconductor device 120 further includes a second metallization layer 124, a third metallization layer 128, a fourth metallization layer 132, and a second dielectric material 134. The second metallization layer 124 can be electrically connected to the first metallization layer 158 of the memory structure 150 by one or more first vias 159. The third metallization layer 128 can be electrically connected to the second metallization layer 124 by one or more second vias 126. The fourth metallization layer 132 can be electrically connected to the third metallization layer 128 by one or more third vias 130. In some embodiments, each of the second and third metallization layers 124, 128 is composed of copper, and the fourth metallization layer 132 is composed of aluminum. In some embodiments, the first and third vias 159, 130 are composed of tungsten, and the second vias 126 are composed of copper. In other embodiments, the aforementioned components of the second semiconductor device 120 can be composed of other suitable materials.

The second dielectric material 134 can be deposited on the first dielectric material 122 to partially enclose the fourth metallization layer 132, the one or more bond pads 138, and one or more vias 137 that interconnect the fourth metallization layer 132 and the one or more bond pads 138. Also, as shown, the second dielectric material 134 can include a layer or plurality of airgaps 136 that extend therethrough (e.g., into the page in FIG. 1). The airgaps 136 can naturally form in spaces generally between portions of the fourth metallization layer 132 when depositing the second dielectric material 134.

One drawback to this arrangement is the challenge associated with fabricating the BEOL stack without the ability to first probe or otherwise test the memory structure 150. For example, probing and testing the memory structure 150 may not only identify defects or inconsistencies in the memory structure 150, but also provide valuable information for designing and optimizing the BEOL interconnects by, for example, precisely mapping electrical characteristics and signal behavior within the memory structure 150. While the exposed portions of the fourth metallization layer 132 can be used for probing and/or testing the semiconductor device assembly 100 as a whole, it is formed towards the end of the BEOL process and therefore cannot be used to improve the earlier portions of the BEOL process (e.g., depositing the second and third metallization layers 124, 128). Additionally, the BEOL stack illustrated in FIG. 1 may affect the performance of the memory structure 150 in unintended and/or undesirable ways.

To address these drawbacks and others, various embodiments of the present application provide semiconductor device assemblies with improved architecture for integrating multiple semiconductor devices. For example, a semiconductor device in accordance with embodiments of the present technology can include two probing layers. The first probing layer can be used for probing and testing a memory structure early in the BEOL process, and the second probing layer can be used for probing and testing the semiconductor device assembly as a whole afterwards. A semiconductor device in accordance with embodiments of the present technology can also include non-standard BEOL interconnects between the first and second probing layers that can improve the performance of the memory structure and thus the semiconductor device assembly.

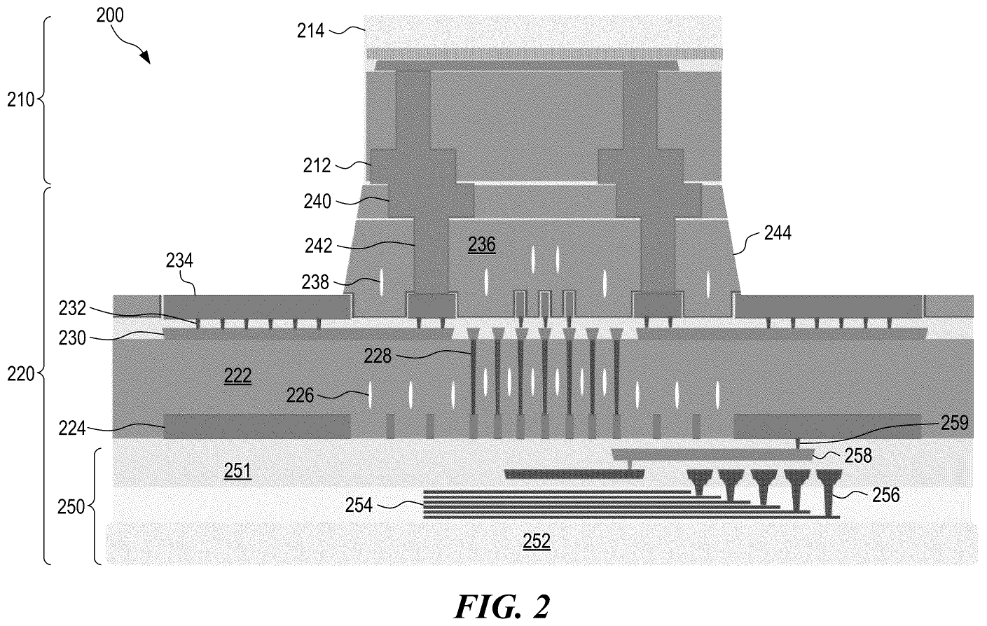

FIG. 2 is a simplified schematic cross-sectional view of a semiconductor device assembly 200 in accordance with embodiments of the present technology. The semiconductor device assembly 200 includes a first semiconductor structure or device 210 stacked on top of a second semiconductor structure or device 220. Each of the first semiconductor device 210 and the second semiconductor device 220 can include a chip, a wafer, or other structure. The first semiconductor device 210 and the second semiconductor device 220 can be bonded together in a face-to-face arrangement via hybrid bonding, oxide bonding, copper bonding, and/or other suitable bonding techniques. For example, the first semiconductor device 210 includes one or more first bond pads 212 and the second semiconductor device 220 includes one or more second bond pads 240 coupled to the one or more first bond pads 212.

The second semiconductor device 220 includes a memory structure 250 (e.g., a 3D memory structure, a NAND structure, a DRAM structure) and non-standard BEOL interconnects deposited on the memory structure 250, as described further herein. The memory structure 250 can include a substrate 252, a plurality of word lines 254, a plurality of bit lines 256, and a first metallization layer 258. The plurality of word lines 254, the plurality of bit lines 256, and the first metallization layer 258 can be deposited in and/or surrounded by a first dielectric layer or material 251 disposed on the substrate 252. In some embodiments, the substrate 252 is composed of silicon, the plurality of word lines 254 and the plurality of bit lines 256 are composed of tungsten, and the first metallization layer 258 is composed of copper. In other embodiments, the aforementioned components of the memory structure 250 can be composed of other suitable materials.

The second semiconductor device 220 further includes a second metallization layer 224, a third metallization layer 230, a fourth metallization layer 234, and a second dielectric layer or material 222. The second metallization layer 224 can be embedded in the second dielectric material 222. Also, the second metallization layer 224 can be electrically connected to the first metallization layer 258 of the memory structure 250 by one or more first vias 259. The third metallization layer 230 can be electrically connected to the second metallization layer 224 by one or more second vias 228. The fourth metallization layer 234 can be at least partially embedded in the third dielectric layer or material 236. Also, the fourth metallization layer 234 can be electrically connected to the third metallization layer 230 by one or more third vias 232. In some embodiments, each of the second and fourth metallization layer 224, 234 is composed of aluminum (e.g., selected for being amenable to probing, testing, and/or wire bonding, as discussed further herein), and the third metallization layer 230 is composed of copper. In some embodiments, the first, second, and third vias 259, 228, 232 are composed of tungsten. In other embodiments, the aforementioned components of the second semiconductor device 220 can be composed of other suitable materials.

As shown in FIG. 2, the second vias 228 extend between the second and third metallization layers 224, 230 through the second dielectric material 222. As discussed further herein, the second dielectric material 222 can have a thickness such that the second vias 228 have high aspect ratios (e.g., relative to the first and third vias 259, 232). Moreover, the second dielectric material 222, which is deposited on the first dielectric material 251, can include a first layer or plurality of airgaps 226 that extend therethrough (e.g., into the page in FIG. 2). The airgaps 226 can naturally form in spaces generally between portions of the second and third metallization layers 224, 230 (e.g., between the second vias 228) when depositing the second dielectric material 222.

Furthermore, the second semiconductor device 220 includes a third dielectric material 236 deposited on the second dielectric material 222 to partially enclose the fourth metallization layer 234, the one or more bond pads 240, and one or more vias 242 that interconnect the fourth metallization layer 234 and the one or more bond pads 240. Also, as shown, the third dielectric material 236 can include a second layer or plurality of airgaps 238 that extend therethrough (e.g., into the page in FIG. 2). The airgaps 238 can naturally form in spaces generally between portions of the fourth metallization layer 234 when depositing the third dielectric material 236. Also, the third dielectric material 236 can have an etching signature 244 at its edges, as discussed further herein.

In some embodiments, the first semiconductor device 210 comprises an analog device. The Back-End of line (BEOL) of the second semiconductor device 220, described above and in further detail herein, can be adapted to interface with the analog device or other device comprising the first semiconductor device 210. In some embodiments, the semiconductor device assembly 200 can form and/or be part of a chip-to-chip assembly.

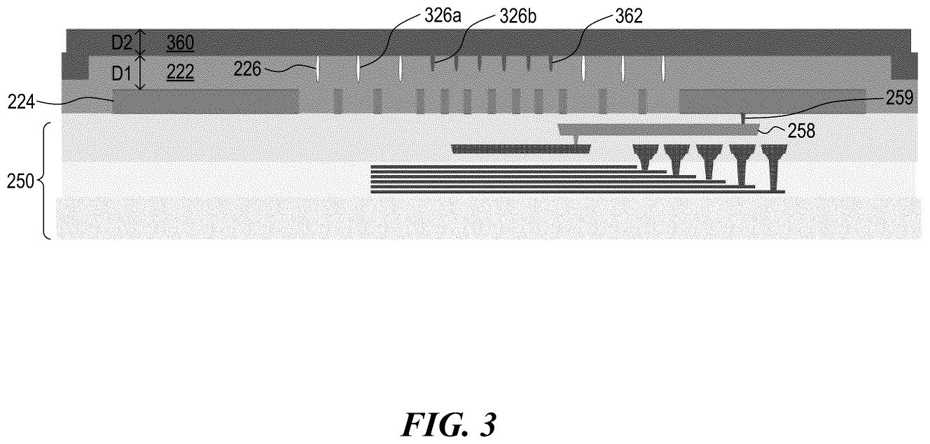

FIG. 3-12 are simplified schematic cross-sectional views illustrating a series of fabrication steps of semiconductor device assemblies in accordance with an embodiment of the present technology. While the figures and the description below reference the semiconductor device assembly 200 illustrated in FIG. 2 and the components thereof, it will be appreciated that the fabrication steps described herein can also be used for semiconductor device assemblies in accordance with other embodiments of the present technology.

Beginning with FIG. 3, the second metallization layer 224 (e.g., aluminum) can be formed on the memory structure 250 and connected to the first metallization layer 258 by the one or more first vias 259. Then, the second dielectric material 222 can be deposited on the second metallization layer 224 via chemical vapor deposition (CVD), epitaxy, plasma-enhanced chemical vapor deposition (PECVD), or other suitable techniques. In some embodiments, the second dielectric material 222 comprises silicon oxide (SiO). The second dielectric material 222 can be deposited to have a thickness D1 above the second metallization layer 224. The thickness D1 can be about 0.6 μm, 0.8 μm, 1 μm, 1.2 μm, 1.4 μm, 0.6-1.4 μm, or other values. In some embodiments, the silicon oxide layer can be formed from a combination of precursor materials such as tetraethyl orthosilicate (TEOS) and silane (SiH4) in varying ratios (e.g., 60% of the SiO layer from TEOS and 40% of the SiO layer from SiH4).

As the second dielectric material 222 is deposited, the first layer of airgaps 226 can be naturally formed laterally between but above portions of the second metallization layer 224 in the process. The position and size of each airgap 226 can vary depending on, for example, the spacing between the portions of the second metallization layer 224. In the illustrated embodiment, the airgaps 226 include a first subset 326a of airgaps that are sealed off within the thickness D1 of the second dielectric material 222 and a second subset 326b of airgaps that have not been completely sealed off within the thickness D1 of the second dielectric material 222.

Next, a passivation layer 360 is deposited on the second dielectric material 222 to have a thickness D2. In some embodiments, the passivation layer 360 comprises silicon nitride (SiN). The thickness D2 can be about 0.4 μm, 0.6 μm, 0.8 μm, 1 μm, 1.2 μm, 0.4-1.2 μm, or other values. As shown, portions 362 of the passivation layer 360 can be deposited in the second subset 326b of airgaps, which have not been completely sealed off, but not in the first subset 326a of airgaps, which have been completely sealed off.

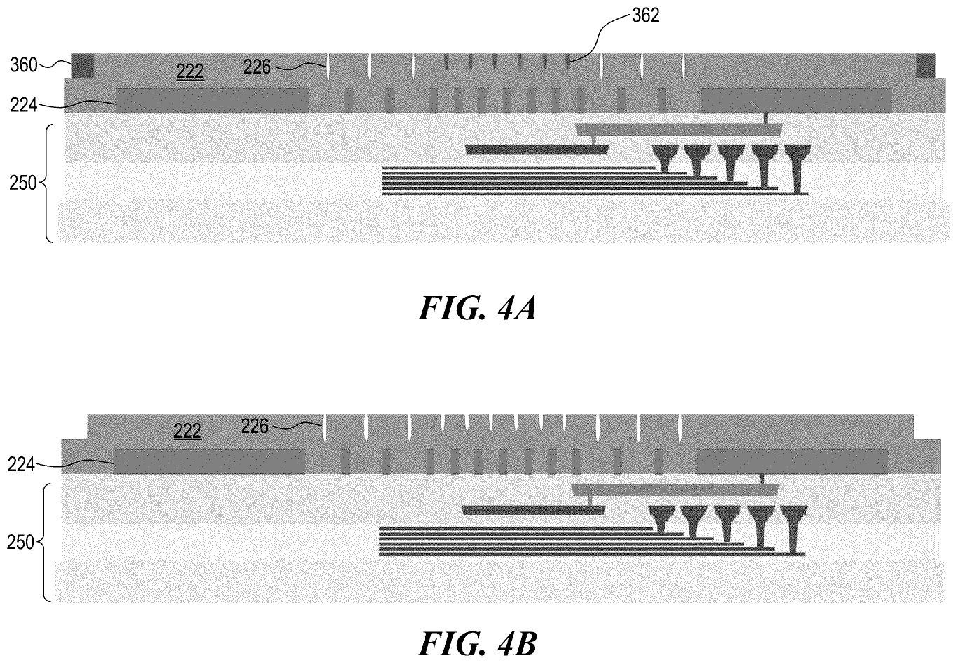

Turning to FIGS. 4A and 4B, the passivation layer 360 can be at least partially removed from the top surface of the second dielectric material 222 via various techniques. Referring first to FIG. 4A, one method of removing the passivation layer 360 is dry etching, which uses reactive gases (e.g., in a plasma) that chemically react with the passivation layer 360. One potential drawback of dry etching is that some of the passivation layer 360 (e.g., the portions 362 thereof) can remain, as illustrated in FIG. 4A. These residues (e.g., nitride residues) can negatively affect the performance of the semiconductor device assembly, such as by creating electrical shorts, and contribute to yield loss. Referring next to FIG. 4B, another method of removing the passivation layer 360 is wet etching, which involves immersing the structure in a liquid chemical solution that selectively dissolves the passivation layer 360. One potential drawback of wet etching is that some of the liquid chemical solution (not shown) can remain trapped in the airgaps 226, which can contribute to corrosion or otherwise harm performance and reliability.

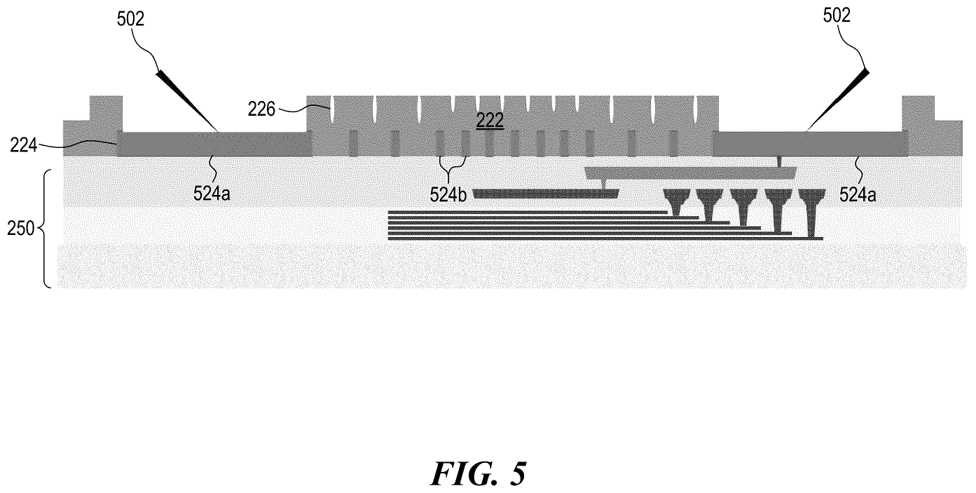

Turning next to FIG. 5, the second metallization layer 224 includes one or more first portions 524a that have relatively greater cross-sectional dimensions, and one or more second portions 524b that have relatively smaller cross-sectional dimensions and, in FIG. 5, positioned between two of the first portions 524a. After the passivation layer 360 is removed, as discussed above with reference to FIGS. 4A and 4B, portions of the second dielectric material 222 that are above the first portions 524a can be removed. In particular, portions of the second dielectric material 222 can be removed to expose the first portions 524a while leaving the airgaps 226 in place. In some embodiments, the exposed first portions 524a can serve as probing pads for probing and/or testing the memory structure 250 via one or more probes 502. As discussed above, probing and/or testing the memory structure 250 early in the BEOL process can provide various insights into the memory structure 250 and how subsequent steps in the fabrication process should be carried out.

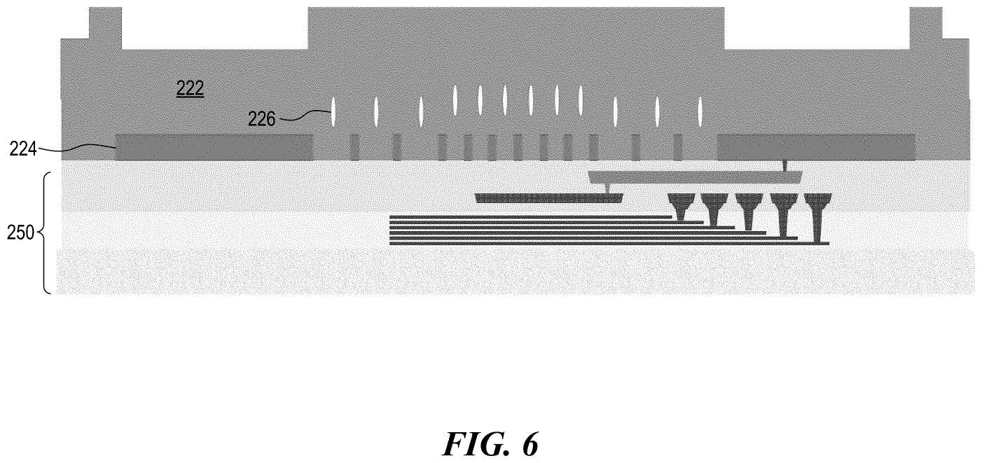

Turning next to FIG. 6, more of the second dielectric material 222 can be deposited on top to increase its thickness. As shown, enough additional layers of the second dielectric material 222 can be added to completely seal off all of the airgaps 226. Also, the second dielectric material 222 can be added uniformly over the structure such that the topography of the top of the second dielectric material 222 in FIG. 6 reflects the topography of the structure in FIG. 5. Thus, the topography of the top of the second dielectric material 222 is non-planar.

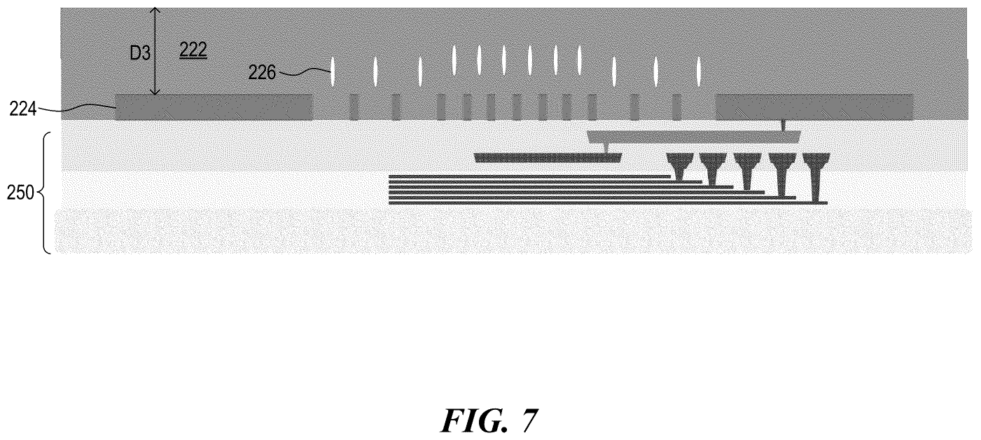

Turning next to FIG. 7, portions of the second dielectric material 222 is removed such that the top of the second dielectric material 222 is planarized and the second dielectric material 222 has a thickness D3 from the second metallization layer 224. In some embodiments, the second dielectric material 222 is planarized via chemical mechanical polishing (CMP). The thickness D3 can be about 1.8 μm, 2 μm, 2.2 μm, 2.4 μm, 2.6 μm, 1.8-22.6 μm, or other values that ensure the airgaps 226 remain completely sealed off.

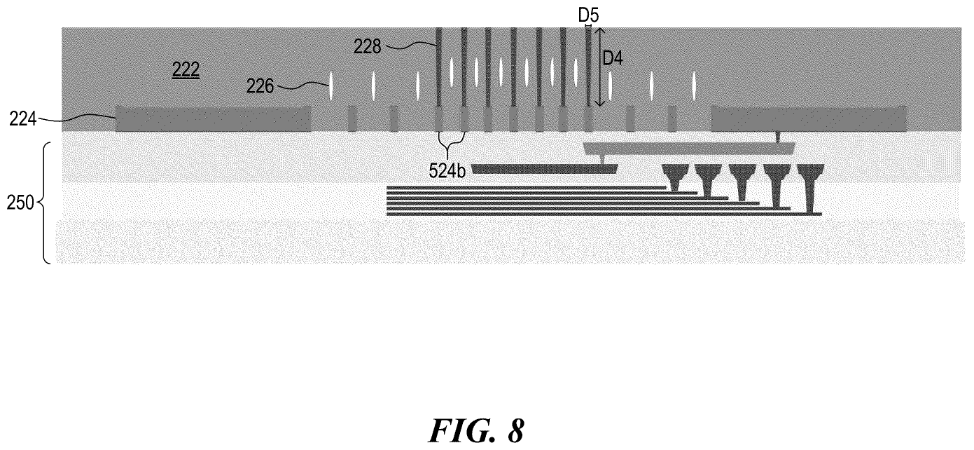

Turning next to FIG. 8, the second vias 228 (e.g., tungsten) can be formed to extend from the second metallization layer 224, through the second dielectric material 222, between the airgaps 226, and be exposed at the top of the second dielectric material 222. In particular, the second vias 228 can extend from the second portions 524b. In some embodiments, the second vias 228 are formed via damascene, dual-damascene, or other suitable processing. The second vias 228 can have a length D4 and a thickness D5. The aspect ratio of each of the second vias 228, defined by D4:D5, can be about 12:1, 14:1, 16:1, 18:1, 20:1, 12:1-20:1, or other ratios.

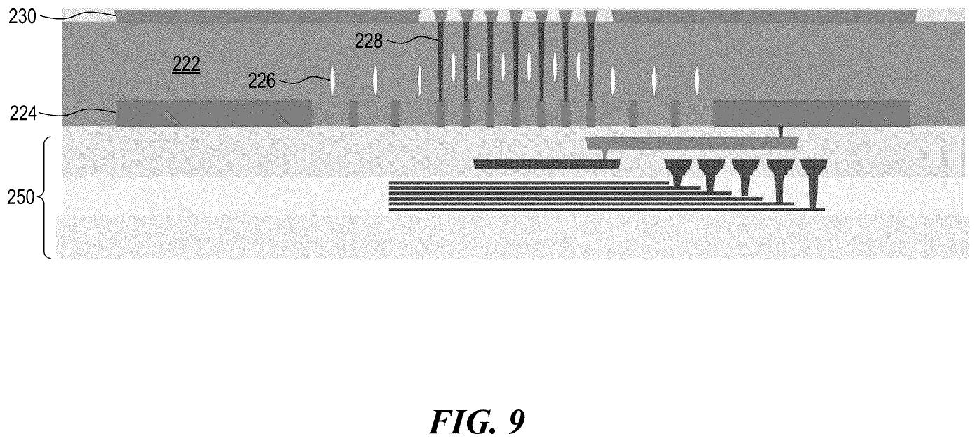

Turning next to FIG. 9, the third metallization layer 230 (e.g., copper) is formed on top of the second dielectric material 222 and connected to the second vias 228. The third metallization layer 230 can be formed in the same or different dielectric material. The third metallization layer 230 is thus electrically connected to the second metallization layer 224 and the memory structure 250.

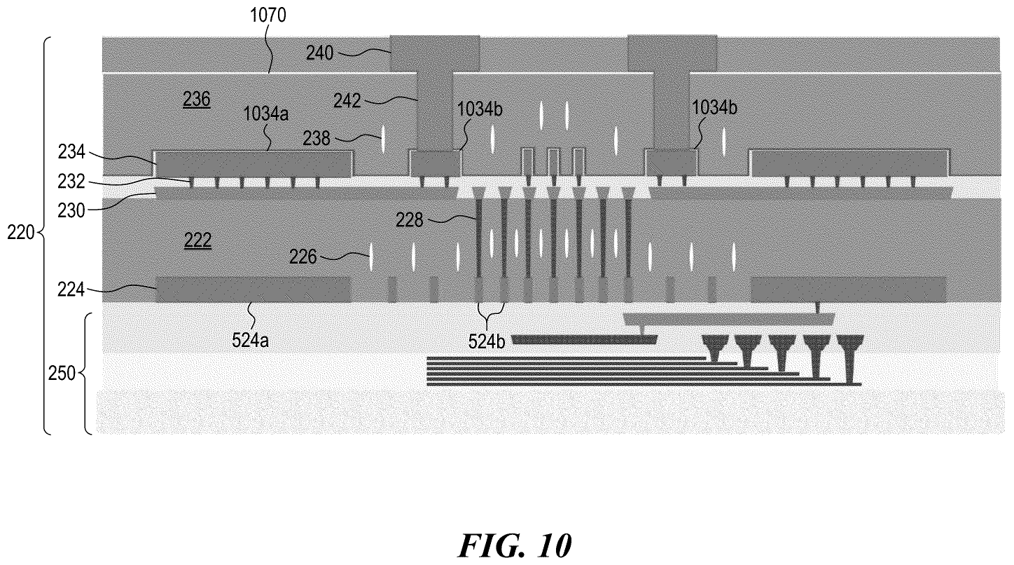

Turning next to FIG. 10, the one or more third vias 232 (e.g., tungsten) are formed to extend from the third metallization layer 230. Then, the fourth metallization layer 234 (e.g., aluminum) is formed above and coupled to the third vias 232. Next, the third dielectric material 236 is deposited over the fourth metallization layer 234. In some embodiments, the third dielectric material 236 is deposited in a manner similar to the second dielectric material 222, as discussed above with reference to FIG. 3. Moreover, the second layer of airgaps 238 can be naturally formed as the third dielectric material 236 is deposited in a manner similar to how the first layer of airgaps 226 were formed.

Then, the bond pads 240 and the vias 242 can be formed in the third dielectric material 236 via damascene, dual-damascene, or other suitable processing. In some embodiments, an etch stop layer 1070 is provided to define the narrower cross-sectional dimension of the vias 242 relative to the bond pads 240. Furthermore, the fourth metallization layer 234 can include first portions 1034a and second portions 1034b. The first portions 1034a can each have a greater cross-sectional dimension than each of the second portions 1034b. The first portions 1034a can be positioned generally vertically aligned with the first portions 524a of the second metallization layer 224, and the second portions 1034b can be positioned generally vertically aligned with the second portions 524b of the second metallization layer 224. Moreover, the vias 242 can be formed to extend between the bond pads 240 and the second portions 1034b of the fourth metallization layer 234.

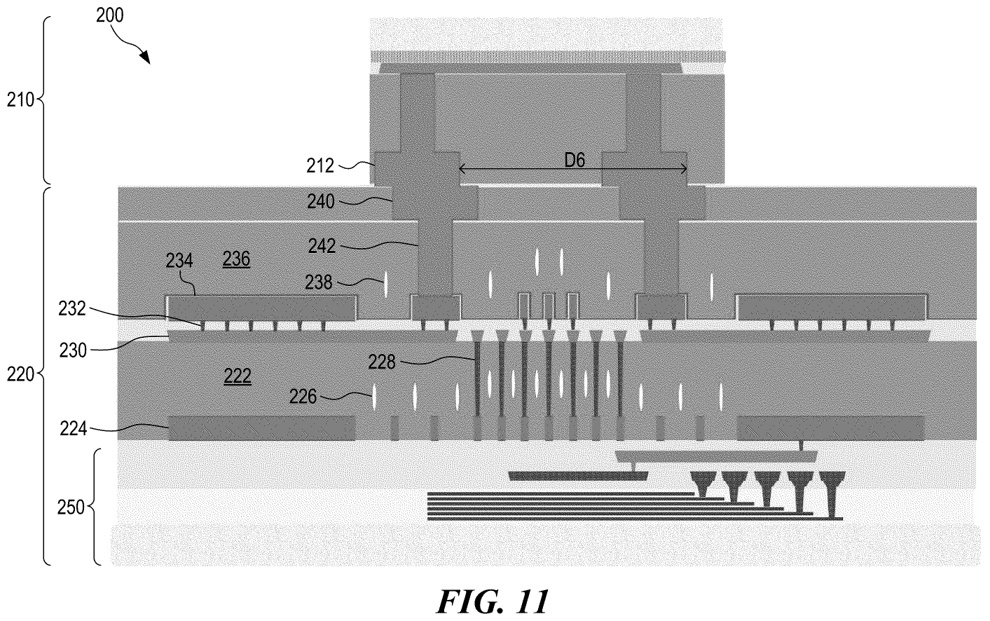

Turning next to FIG. 11, the first semiconductor device 210 is bonded to the second semiconductor device 210 via hybrid bonding, oxide bonding, copper bonding, and/or other suitable bonding techniques. For example, the bond pads 212 of the first semiconductor device 210 can be bonded to the bond pads 240 of the second semiconductor device 220. Moreover, as shown, the first and second semiconductor devices 210, 220 can be bonded in a face-to-face arrangement such that the substrate 214 of the first semiconductor device 210 is positioned at the top. The bond pads 212 can be separated such that edges of the bond pads 212 are spaced apart by a distance D6, which can be about 6 μm, 8 μm, 10 μm, 12 μm, 14 μm, 6-14 μm, or other values.

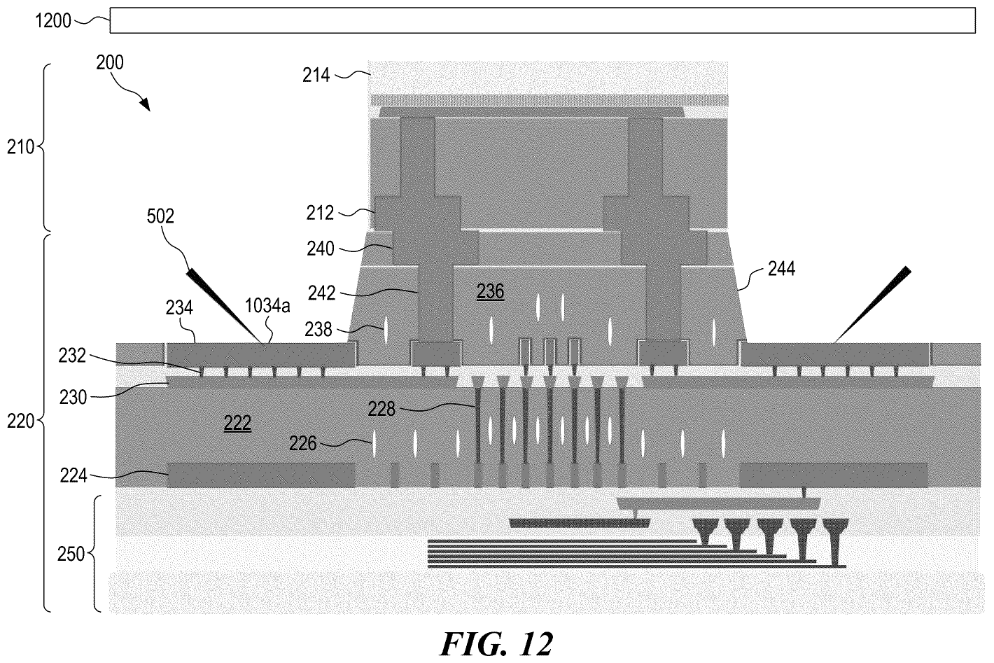

Turning next to FIG. 12, an etching tool 1200 can be positioned over the first semiconductor device 210. The etching tool 1200 can be used to remove portions of the third dielectric material 236 via photolithography or other suitable techniques. In particular, the third dielectric material 236 can be removed until the third dielectric material 236 no longer extends across the first portions 1034a of the fourth metallization layer 234, exposing the first portions 1034a at, for example, either side of the bond pads 240 and the vias 242. When removing portions of the third dielectric material 236, the substrate 214 of the first semiconductor device 210, which is positioned at the top facing the etching tool 1200, can serve as a mask to prevent etching or removal of the third dielectric material 236 around the bond pads 240, the vias 242, and the second layer of airgaps 238. This can leave the etching signature 244 at the edges of the third dielectric material 236. The exposed first portions 1034a of the fourth metallization layer 234 can subsequently be used for probing and/or testing of the semiconductor device assembly 200 as a whole.

The semiconductor device assembly 200 can be subsequently attached to another component for further packaging, such as a package substrate. In some embodiments, the exposed first portions 1034a of the fourth metallization layer 234 can be used for wire bonding to the package substrate (or other component). The semiconductor device assembly 200 can also be at least partially encapsulated in an encapsulant (e.g., mold, epoxy, or other resin-based structure).

The resulting architecture of the semiconductor device assembly 200 includes non-standard BEOL interconnects that enable an improved connection between the first semiconductor device 210 and the second semiconductor device 220 compared to, for example, the semiconductor device assembly 100 illustrated in FIG. 1. First, having two distinct probing layers, namely the second metallization layer 224 and the fourth metallization layer 234, can allow probing and/or testing of the memory structure 250 early in the BEOL process before the other layers are constructed, as well as after the fabrication of the semiconductor device assembly 200. Probing and/or testing the memory structure 250 may not only identify defects or inconsistencies in the memory structure 250, but also provide valuable information for designing and optimizing the BEOL interconnects by, for example, precisely mapping electrical characteristics and signal behavior within the memory structure 250.

Second, probing and testing (and scrubbing) the memory structure 250 via the second metallization layer 224 can cause damage that may render the second metallization layer 224 unsuitable for subsequently depositing additional layers and forming a planar surface suitable for hybrid bonding. Thus, forming the fourth metallization layer 234 above the second metallization layer 224 can allow (i) a planar surface to be formed on top, (ii) proper hybrid bonding, and (iii) subsequent probing and/or testing of the semiconductor device assembly 200 regardless of the damage done to the second metallization layer 224. In other words, the architecture illustrated and described herein preserves the ability to form hybrid bonding.

Third, in some embodiments, the second vias 228 can provide a direct connection between the first semiconductor device 210 and the memory structure 250. For example, the semiconductor device assembly 100 illustrated in FIG. 1 includes multiple copper layers between the memory structure 150 and the metallization layer that provides probing pads (e.g., the fourth metallization layer 132). These multiple copper layers can, in some cases, negatively affect the performance of the memory structure 150 when integrated with the first semiconductor device 110. In contrast, the semiconductor device assembly 200 of FIGS. 2-12 includes a more direct connection between the first semiconductor device 210 and the memory structure 250 (e.g., through the second vias 228).

Also, while the semiconductor device assembly 200 includes two probing layers (e.g., the second and fourth metallization layers 224, 234) and the second vias 228 having high aspect ratios, the lack of the stack of copper layers shown in FIG. 1 allows sufficient vertical space to keep the total vertical height of the semiconductor device assembly 200 comparable to the vertical height of the semiconductor device assembly 100.

Additionally, unlike the semiconductor device assembly 100, the semiconductor device assembly 200 includes two layers of airgaps: the first layer of airgaps 226 in the second dielectric material 222 and the second layer of airgaps 238 in the third dielectric material 236. While the airgaps 226, 238 are naturally formed during the deposition of the dielectric materials, as discussed above, the airgaps 226, 238 can have a lower dielectric constant (e.g., compared to the second and third dielectric materials 222, 236) and can provide the benefits of lowering parasitic capacitance, improving signal integrity, lowering power consumption, improving thermal management, etc.

Although in the foregoing example embodiment, semiconductor device assemblies have been illustrated and described as including two semiconductor device, in other embodiments, assemblies can be provided with additional semiconductor devices. For example, the second semiconductor device 220 can be a much larger device than illustrated on which multiple chips are stacked thereon. In another example, the second semiconductor device 220 can be replaced by a stack of semiconductor devices. Also, the memory structure 250 can be replaced with other semiconductor structures and the BEOL interconnects described herein can be fabricated on those other structures.

In accordance with one aspect of the present disclosure, the semiconductor devices illustrated in the assemblies of FIGS. 2-12 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

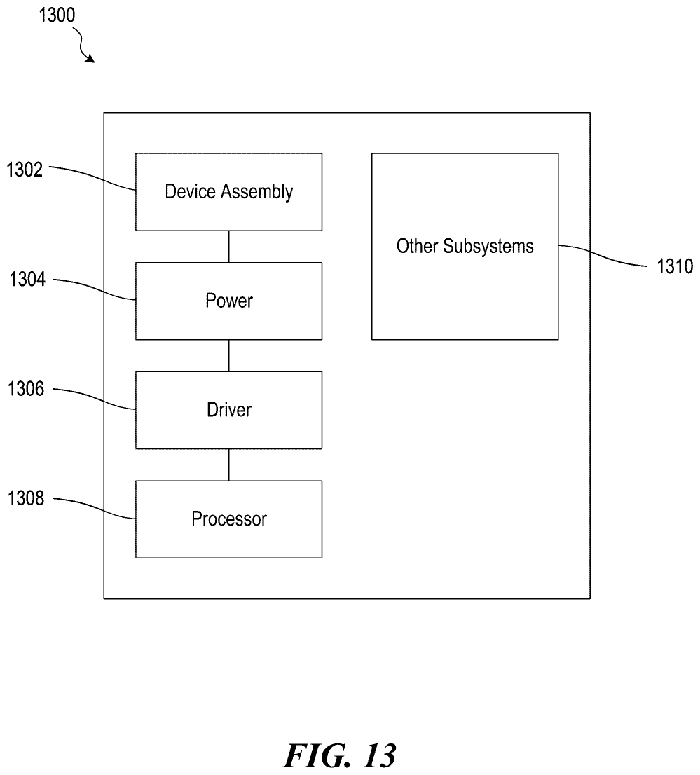

Any one of the semiconductor devices and semiconductor device assemblies described above with reference to FIGS. 2-12 can be incorporated into any of a myriad of larger and/or more complex systems, a representative example of which is system 1300 shown schematically in FIG. 13. The system 1300 can include a semiconductor device assembly (e.g., or a discrete semiconductor device) 1302, a power source 1304, a driver 1306, a processor 1308, and/or other subsystems or components 1310. The semiconductor device assembly 1302 can include features generally similar to those of the semiconductor devices described above with reference to FIGS. 2-12. The resulting system 1300 can perform any of a wide variety of functions, such as memory storage, data processing, and/or other suitable functions. Accordingly, representative systems 1300 can include, without limitation, hand-held devices (e.g., mobile phones, tablets, digital readers, and digital audio players), computers, vehicles, appliances and other products. Components of the system 1300 may be housed in a single unit or distributed over multiple, interconnected units (e.g., through a communications network). The components of the system 1300 can also include remote devices and any of a wide variety of computer readable media.

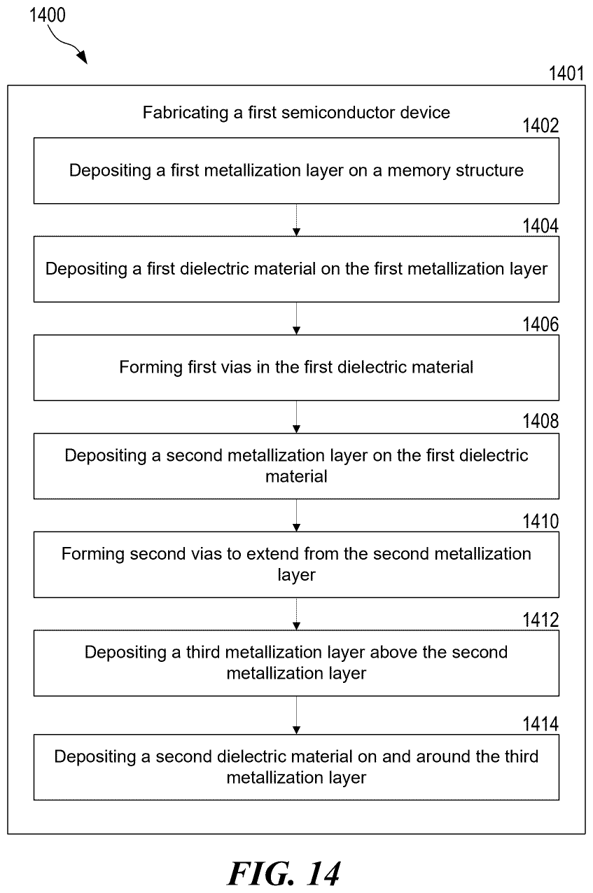

FIG. 14 is a flow chart illustrating a method 1400 of making a semiconductor device assembly (e.g., the semiconductor device assembly 200) in accordance with an embodiment of the present technology. While the method 1400 is described below with reference to the embodiments illustrated in FIGS. 2-12, it will be appreciated that the method 1400 can be performed to make other embodiments of semiconductor device assemblies. Also, while the steps of the method 1400 are described in a particular order herein, one or more of the steps can be performed in a different order, or omitted entirely. Moreover, the method 1400 can include additional or alternative steps not necessarily described herein. The method 1400 begins at block 1401 by fabricating a first semiconductor device (e.g., the first semiconductor device 220), which can include the following steps.

At block 1402, the method 1400 includes depositing a first metallization layer on a memory structure (e.g., FIG. 3). At block 1404, the method 1400 continues by depositing a first dielectric material on the first metallization layer, wherein depositing the first dielectric material forms a first plurality of airgaps in the first dielectric material. In some embodiments, fabricating the first semiconductor device (block 1401) further includes (i) depositing a passivation layer on the first dielectric material, and (ii) removing, at least partially, the passivation layer via dry etching or wet etching. The passivation layer can be deposited in at least some of the first plurality of airgaps.

In some embodiments, fabricating the first semiconductor device further includes (i) removing portions of the first dielectric material to expose portions of the first metallization layer, (ii) probing, via the exposed portions of the first metallization layer, the memory structure, and (iii) depositing additional layers of the first dielectric material to bury the first metallization layer and to fully encapsulate the first plurality of airgaps. In some embodiments, fabricating the first semiconductor device further includes planarizing the first dielectric material via, e.g., chemical mechanical planarization (CMP).

At block 1406, the method 1400 continues by forming first vias in the first dielectric material, wherein each of the first vias extends from the first metallization layer and has an aspect ratio of at least 10:1. At block 1408, the method 1400 continues by depositing a second metallization layer on the first dielectric material such that the first vias extend between the first and second metallization layers. At block 1410, the method 1400 continues by forming second vias to extend from the second metallization layer.

At block 1412, the method 1400 continues by depositing a third metallization layer above the second metallization layer such that the second vias extend between the second and third metallization layers. At block 1414, the method 1400 continues by depositing a second dielectric material on and around the third metallization layer, wherein depositing the second dielectric material forms a second plurality of airgaps in the second dielectric material. In some embodiments, fabricating the first semiconductor device (block 1401) further comprises forming (i) one or more bond pads in the second dielectric material and (ii) one or more third vias that extend between corresponding ones of the bond pads and the third metallization layer.

In some embodiments, the method 1400 further includes (i) bonding a second semiconductor device to the one or more bond pads of the first semiconductor device in a face-to-face arrangement, (ii) removing portions of the second dielectric material to expose portions of the third metallization layer, and (iii) probing, via the exposed portions of the third metallization layer, the semiconductor device assembly.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a first dielectric material having a first plurality of airgaps;
a first metallization layer embedded in the first dielectric material;
a second dielectric material disposed above the first dielectric material and having a second plurality of airgaps;
a second metallization layer disposed between the first dielectric material and the second dielectric material;
one or more first vias extending through the first dielectric material between the first metallization layer and the second metallization layer, wherein each of the one or more first vias has an aspect ratio of at least 10:1;
a third metallization layer at least partially embedded in the second dielectric material, wherein the second metallization layer is disposed between the first metallization layer and the third metallization layer; and
one or more second vias extending between the second metallization layer and the third metallization layer.

2. The semiconductor device of claim 1, wherein each of the one or more first vias has an aspect ratio of at least 16:1.

3. The semiconductor device of claim 1, wherein each of the first metallization layer and the third metallization layer comprises aluminum.

4. The semiconductor device of claim 1, wherein the second metallization layer comprises copper.

5. The semiconductor device of claim 1, wherein each of the one or more first vias comprises tungsten.

6. The semiconductor device of claim 1, wherein the first dielectric material has a thickness of at least 2.2 μm.

7. The semiconductor device of claim 1, wherein the first metallization layer comprises first portions and second portions, wherein each of the first portions has a greater cross-sectional dimension than each of the second portions, and wherein the one or more first vias extend only from the second portions, and not the first portions, of the first metallization layer.

8. The semiconductor device of claim 1, wherein the third metallization layer comprises first portions and second portions, wherein each of the first portions has a greater cross-sectional dimension than each of the second portions, and wherein the second dielectric material does not extend over the first portions of the third metallization layer.

9. The semiconductor device of claim 1, further comprising one or more bond pads embedded in the second dielectric material and one or more third vias extending through the second dielectric material between corresponding ones of the one or more bond pads and the third metallization layer.

10. A method of making a semiconductor device assembly, the method comprising:
fabricating a first semiconductor device, wherein fabricating comprises:
depositing a first metallization layer on a memory structure;
depositing a first dielectric material on the first metallization layer, wherein depositing the first dielectric material forms a first plurality of airgaps in the first dielectric material;
forming first vias in the first dielectric material, wherein each of the first vias extends from the first metallization layer and has an aspect ratio of at least 10;
depositing a second metallization layer on the first dielectric material such that the first vias extend between the first and second metallization layers;
forming second vias to extend from the second metallization layer;
depositing a third metallization layer above the second metallization layer such that the second vias extend between the second and third metallization layers; and
depositing a second dielectric material on and around the third metallization layer, wherein depositing the second dielectric material forms a second plurality of airgaps in the second dielectric material.

11. The method of claim 10, wherein fabricating the first semiconductor device further comprises:
removing portions of the first dielectric material to expose portions of the first metallization layer;
probing, via the exposed portions of the first metallization layer, the memory structure; and
depositing additional layers of the first dielectric material to bury the first metallization layer and to fully encapsulate the first plurality of airgaps.

12. The method of claim 11, wherein fabricating the first semiconductor device further comprises:
prior to forming the first vias in the first dielectric material, planarizing the first dielectric material via chemical mechanical planarization (CMP).

13. The method of claim 10, wherein fabricating the first semiconductor device further comprises forming (i) one or more bond pads in the second dielectric material and (ii) one or more third vias that extend between corresponding ones of the bond pads and the third metallization layer.

14. The method of claim 13, further comprising:
bonding a second semiconductor device to the one or more bond pads of the first semiconductor device in a face-to-face arrangement;
removing portions of the second dielectric material to expose portions of the third metallization layer; and
probing, via the exposed portions of the third metallization layer, the semiconductor device assembly.

15. The method of claim 10, wherein fabricating the first semiconductor device further comprises:
depositing a passivation layer on the first dielectric material, wherein the passivation layer is deposited in at least some of the first plurality of airgaps; and
removing, at least partially, the passivation layer via dry etching or wet etching.

16. A semiconductor device assembly, comprising:
a first semiconductor device including:
a first dielectric material having a first plurality of airgaps;
a first metallization layer embedded in the first dielectric material;
a second dielectric material disposed above the first dielectric material and having a second plurality of airgaps;
a second metallization layer disposed between the first dielectric material and the second dielectric material;
one or more first vias extending through the first dielectric material between the first metallization layer and the second metallization layer, wherein each of the one or more first vias has an aspect ratio of at least 10;
a third metallization layer at least partially embedded in the second dielectric material, wherein the second metallization layer is disposed between the first metallization layer and the third metallization layer;
one or more second vias extending between the second metallization layer and the third metallization layer; and
one or more bond pads embedded in the second dielectric material; and
a second semiconductor device bonded to the first semiconductor device in a face-to-face arrangement.

17. The semiconductor device assembly of claim 16, wherein each of the first metallization layer and the third metallization layer comprises aluminum, wherein each of the second metallization layer and the bond pads comprises copper, and wherein each of the first vias comprises tungsten.

18. The semiconductor device assembly of claim 16, wherein the first dielectric material has a thickness of at least 2.2 μm, and wherein each of the first vias has an aspect ratio of at least 16.

19. The semiconductor device assembly of claim 16, wherein the second dielectric material has an edge with an etching signature.

20. The semiconductor device assembly of claim 16, wherein the third metallization layer comprises first portions and second portions, wherein each of the first portions has a greater cross-sectional dimension than each of the second portions, wherein the second dielectric material does not extend over the first portions of the third metallization layer, and wherein the second semiconductor device is positioned over only the second portions, and not the first portions, of the third metallization layer.
